(19) United States
(12) Patent Application Publication
(10) Pub. No.: US 2009/0102479 A1
(43) Pub. Date: Apr. 23, 2009

(54) MRI Phase Visualization of Interventional Devices

(76) Inventors: Scott R. Smith, Chaska, MN (US); Greig Cameron Scott, Palo Alto, CA (US)

Correspondence Address: FISH & RICHARDSON P.C., PO BOX 1022, MINNEAPOLIS, MN, 55440-1022, US

(21) Appl. No.: 12/235,403

(22) Filed: Sep. 22, 2008

Related U.S. Application Data
(60) Provisional application No. 60/974,760, filed on Sep. 24, 2007.

(51) Int. Cl. G01R 33/483; G01R 33/32

(52) U.S. Cl. 324/309; 600/423

(57) ABSTRACT

Imaging a device in a magnetic resonance imaging system includes inserting a device having a conductive coil assembly thereon into a subject, obtaining a magnetic resonance image of the subject that includes signal phase variations, determining a position of the device based on discontinuities in the signal phase variations, and displaying an image representation of the device superimposed on a reference image based upon the determined position.

### CROSS-REFERENCE TO RELATED APPLICATIONS

This application claims priority to U.S. Provisional Application Ser. No. 60/974,760, filed Sep. 24, 2007, the contents of which are hereby incorporated by reference.

### TECHNICAL FIELD

This disclosure relates to medical devices used in MRI visualization.

### BACKGROUND

Interventional medical devices such as guide wires, catheters, electrode needles and biopsy needles are used for a variety of different treatments, for example delivery of a stent within a patient. Tracking of catheters and other devices positioned within a body can be achieved by means of an imaging systems such as x-ray angiography or magnetic resonance imaging (MRI). X-ray angiography systems have difficulty distinguishing between various tissues within a patient. MRI systems have the ability to distinguish between different types of tissues and thus provide benefits over an x-ray system. However, real-time tracking using MRI is susceptible to noise and orientation of devices are difficult to determine. Typically, such a magnetic resonance imaging system may include a magnet, a pulsed magnetic field gradient generator, a transmitter for transmitting electromagnetic waves in radio frequency (RF), a radio frequency receiver, and a controller.

In a common tracking implementation, an antenna is disposed either on the device to be tracked or on a guidewire or catheter (commonly referred to as an MR catheter) used to assist in the delivery of the device to its destination. In one known implementation, the antenna comprises an electrically conductive coil that is coupled to a pair of elongated electrical conductors that are electrically insulated from each other and that together comprise a transmission line adapted to transmit the detected signal to the RF receiver.

In one embodiment, the coil is arranged in a solenoid configuration. The patient is placed into or proximate the magnet and the device is inserted into the patient. The magnetic resonance imaging system generates electromagnetic waves in radio frequency and magnetic field gradient pulses that are transmitted into the patient and that induce a resonant response signal from selected nuclear spins within the patient. This response signal induces current in the coil of electrically conductive wire attached to the device. The coil thus detects the nuclear spins in the vicinity of the coil. The transmission line transmits the detected response signal to the radio frequency receiver, which processes it and then stores it with the controller. This process is repeated in three orthogonal directions. The gradients cause the frequency of the detected signal to be directly proportional to the position of the radio-frequency coil along each applied gradient. Other reconstruction techniques are known, including two dimensional, radial and spiral methods.

The position of the radio frequency coil inside the patient may therefore be calculated by processing the data using Fourier transformations so that a positional picture of the coil is achieved. In one implementation this positional picture is superposed with a background magnetic resonance image of the region of interest. The positional picture can be displayed in a different color from the background image. The background image of the region can be taken and stored at the same time as the positional picture or at any earlier time. Although the position of the coil can be determined, real time tracking and visualizing of the coil is still susceptible to noise.

### SUMMARY

In one aspect, a method of imaging a device in a magnetic resonance imaging system includes inserting a device having a conductive coil assembly thereon into a subject, obtaining a magnetic resonance image of the subject that includes signal phase variations, determining a position of the device based on discontinuities in the signal phase variations, and displaying an image representation of the device superimposed on a reference image based upon the determined position.

In another aspect, a method of imaging an elongate device in a magnetic resonance imaging system includes placing an elongate conductive coil assembly along a length of the device. A magnetic resonance image is obtained containing signal phase variations. An image representation of the length of the device is generated based upon the signal phase variations.

In another aspect, a magnetic resonance imaging system includes a radio frequency (RF) source, an elongate conductive coil positioned to receive RF signals from the RF source, an RF receiver positioned to receive RF signals from the RF source, and a controller operably coupled to the conductive coil and the RF receiver and adapted to generate an image representation of a length of a coil based on signal phase variations received by at least one of the elongate coil and the RF receiver.

In another aspect, a magnetic resonance imaging system includes means for obtaining a magnetic resonance image containing signal phase variations, and means for generating an image representation of a length of an elongate conductive coil based on the signal phase variations.

In another aspect, an invasive medical device includes an elongated body having a conductive coil assembly thereon, and a plurality of regions formed of materials with different magnetic susceptibility.

Implementations of any of the above aspects can include one or more of the following features. Determining the position of the device can include detection of the discontinuities in the signal phase variations by a processor, and determining the position of the device can include pattern recognition of the magnetic resonance image by a processor. Signal phase variations may be detected using the conductive coil assembly, or using an external coil of the magnetic resonance imaging system. The magnetic resonance image may include a magnitude signal and the generating step may include applying a mask generated from the magnitude signal to the image representation. The device can be elongate, and the coil can be elongate. The elongate conductive coil assembly may be a double helix coil, a single helical loop coil with center return, a twisted twin lead coil, a coil having a convoluted path, or coil having alternative opposed solenoid coils. Signal phase variations in the magnetic resonance image may be unwrapped. Shear may be distinguished from phase wrap using a temporal filter or by varying phase shifting. An RF excitation signal may be applied through the coil assembly. The magnetic resonance image may be obtained using the coil assembly. The susceptibility of the coil assembly may be used to cause a local phase shift. Additional phase and coding pulses, such as dephasing pulses, may be transmitted through the coil assembly. A location of the coil assembly may be identified using phase residues. Phased noise may be reduced using a mask generated from signal magnitude. Generating an image may include using phase derivative variants to detect shear. Generating an image may include calculating maximum phase gradient from locally unwrapped phase data. The coil assembly may have a variable sensitivity pattern along a length of the coil assembly. The plurality of regions of different magnetic susceptibility can form a pattern, e.g., alternating bands of different magnetic susceptibility. The device can be a guide wire, catheter, electrode needle or biopsy needle.

In another aspect, a computer program product, i.e., a computer program tangibly embodied in a machine readable storage media, can cause a processor to carry out the computational aspects of the methods described above.

The details of one or more embodiments are set forth in the accompanying drawings and the description below. Other features, objects, and advantages will be apparent from the description and drawings, and from the claims.

### BRIEF DESCRIPTION OF DRAWINGS

FIG. 1 is a partial block diagram of an illustrative magnetic resonance imaging and intravascular guidance system.

FIG. 2 is a schematic illustration of a system for enhancing an MRI signal.

FIG. 3 is a flow diagram of an exemplary process for tracking a device with the system of FIG. 1.

FIG. 4 is a cut away view showing an elongate coil assembly.

FIG. 5 is a cut away view showing an elongate coil assembly.

FIGS. 6A, 6B and 6C are diagrams that illustrate coil orientation relative to orientation of a magnetic resonant image “slice.”

Like reference symbols in the various drawings indicate like elements.

### DETAILED DESCRIPTION

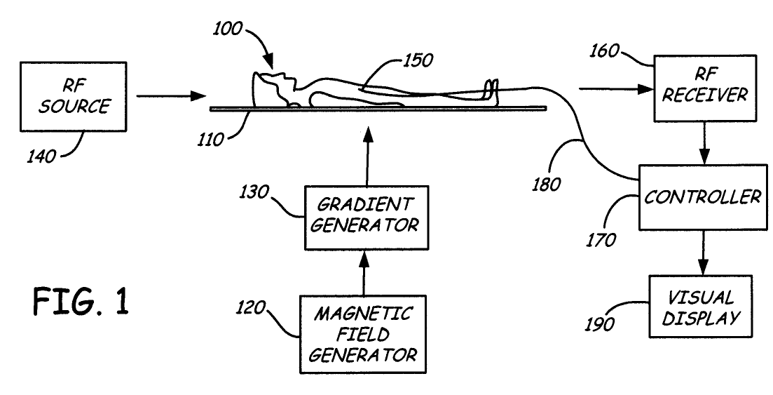

FIG. 1 is a partial block diagram of an illustrative magnetic resonance imaging and intravascular guidance system in which embodiments could be employed. In FIG. 1, subject 100 on support table 110 is placed in a homogeneous magnetic field generated by magnetic field generator 120. Magnetic field generator 120 typically comprises a cylindrical magnet adapted to receive subject 100. Magnetic field gradient generator 130 creates magnet field gradients of predetermined strength in three mutually orthogonal directions at predetermined times (e.g., in a first direction for slice selection, in a second direction prior to data acquisition for phase encoding, and in a third direction during data acquisition for frequency encoding). Magnetic field gradient generator 130 is illustratively comprised of a set of cylindrical coils concentrically positioned within magnetic field generator 120. A region of subject 100 into which a device 150, shown as a catheter, is inserted, is located in the approximate center of the bore of magnet 120. The device 150 can include a magnetic resonance (MR) active material.

RF source 140 radiates pulsed radio frequency energy into subject 100 and the MR active material within device 150 at predetermined times and with sufficient power at a predetermined frequency to nutate nuclear magnetic spins in a fashion well known to those skilled in the art. The nutation of the spins causes them to resonate at the Larmor frequency. The Larmor frequency for each spin is directly proportional to the strength of the magnetic field experienced by the spin. This field strength is the sum of the static magnetic field generated by magnetic field generator 120 and the local field generated by magnetic field gradient generator 130. In an illustrative embodiment, RF source 140 can comprise a cylindrical external coil that surrounds the region of interest of subject 100. Such an external coil can have a diameter sufficient to encompass the entire subject 100. Other geometries, such as smaller cylinders specifically designed for imaging the head or an extremity can be used instead. Non-cylindrical external coils such as surface coils may alternatively be used.

Device 150 is inserted into subject 100 by an operator. Device 150 may be a guide wire, a catheter, a filter, an ablation device or a similar recanalization or other device. The device 150 can include a magnetic resonance (MR) active material. Device 150 can also include a device antenna, e.g., a coil assembly, discussed below that can be used to detect MR signals generated in both the subject and the device 150 itself in response to the radio frequency field created by RF source 140. Signals detected by the device coil assembly are sent to imaging and tracking controller unit 170 via conductor 180.

In one embodiment, device 150 includes an elongate conductive coil to track and visualize the location and orientation of device 150. Many different coil structures can be used such as a double helix loop coil, single helical loop coil with center return, twisted twin lead coil, a coil having a convoluted path and alternatively opposed solenoid coils in series. It can be beneficial for the sensitivity and phase pattern of the coil for the coil assembly to have a unique or distinctive appearance, e.g., for the coil assembly to include groups of coils that are spaced-apart with regular spacing.

External RF receiver 160 detects RF signals in response to the radio frequency field created by RF source 140. In an illustrative embodiment, external RF receiver 160 is a cylindrical external coil that surrounds the region of interest of subject 100. Such an external coil can have a diameter sufficient to encompass the entire subject 100. Other geometries, such as small cylinders specifically designed for imaging the head or an extremity can be used instead. Non-cylindrical external coils, such as surface coils, may alternatively be used.

External RF receiver 160 can share some or all of its structure with RF source 140 or can have a structure entirely independent of RF source 140. The region of sensitivity of RF receiver 160 is larger than that of the device antenna and can encompass the entire subject 100 or a specific region of subject 100. However, the resolution that can be obtained from external RF receiver 160 is less than that which can be achieved with the device antenna. Likewise, the signal to noise ratio can often be improved using a device antenna. The RF signals detected by external RF receiver 160 are sent to imaging and tracking controller unit 170 where they are analyzed together with RF signals detected by the device antenna. In accordance with some embodiments, phase information detected by the device antenna and/or RF receiver 160 is used for determining the position and orientation of device 150.

The position and orientation of device 150 is determined in imaging and tracking controller unit 170 and is displayed on visual display 190, e.g., a computer screen. The controller unit 170 can detect artifacts, e.g., discontinuities, in the phase variation, and determines the position and orientation based on the detected discontinuities. In particular, an image representation of device 150 can be superimposed on a reference image, with the position of the image representation in the reference image based upon the determined position. The image representation can be a portion of a phase image, e.g., a phase variation image that is masked to show substantially only the device, or a graphical symbol. For example, controller unit 170 can derive a phase image of the subject from information detected by the device antenna and/or RF receiver 160, and display the phase image on visual display 190. The reference image can be a simultaneously obtained conventional background MR image, e.g., a magnitude image, obtained by external RF receiver 160, or a stored image.

In an illustrative embodiment, the position of device 150 is displayed on visual display 190 by superposition of a graphic symbol on a conventional background MR image obtained by external RF receiver 160. The position can be displayed in a different color from the background image. Alternatively, background images can be acquired with external RF receiver 160 prior to initiating tracking and a symbol representing the location of the tracked device can be superimposed on the previously acquired image. Alternative embodiments display the position of the device numerically or as a graphic symbol without reference to a diagnostic image.

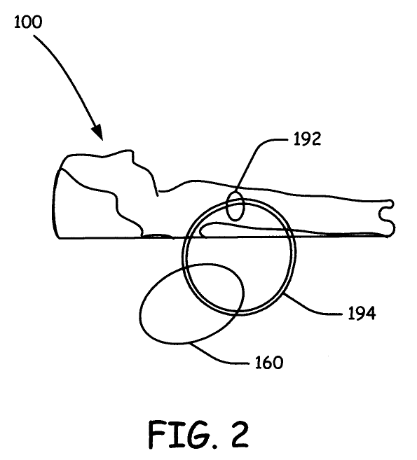

When performing MRI, tuning the resonant frequency of the implanted device antenna (e.g., coil) to the Larmor frequency of the surrounding protons enhances their MR visibility. Using a receiver coil outside the body, as illustrated with respect to coil 160 in FIG. 1, the resonating circuit inside the body induces current in the receiver coil 160 outside the body, and by this configuration, the MR signal from the area directly surrounding the implanted device can be enhanced. This effect is better illustrated with respect to FIG. 2.

As shown in FIG. 2, coil 192 is implanted within subject 100. Receiver coil 160 resides outside of subject 100. The magnetic field lines (shown generally at 194) of implanted coil 192 passes through a receiver coil 160 positioned outside of subject 100. As discussed above, receiver coil 160 is connected to further electronics to enable visualization. Thus, resident coil 192 induces currents in receiver coil 160 which enhances the MR signal in the area directly surrounding coil 192. As discussed above, it is desirable to match the resonating frequency of the resident coil 192 to the Larmor frequency (63.6 MHz at 1.5 tesla or 42.4 MHz per tesla). Although the coil 192 can be the device coil on the device 150, in some implementations the coil 192 can actually be a separately implanted coil that is proximate the device 150 inside the subject 100.

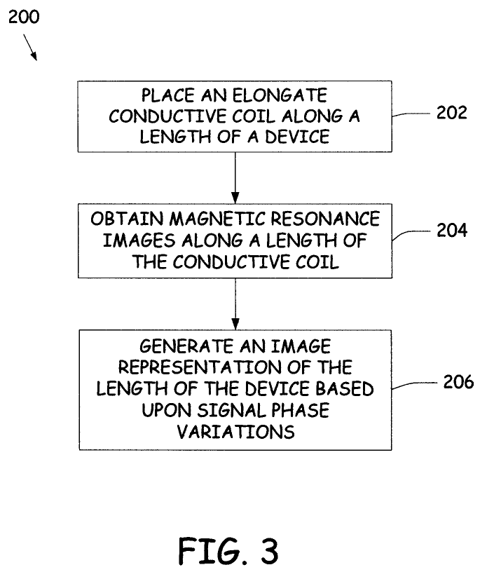

FIG. 3 is an illustrative flow diagram of a method for utilizing phase information in order to visualize and track device 150. Method 200 begins at step 202, wherein an elongate conductive coil is placed along a length of device 150. As discussed earlier, the elongate conductive coil can be for example a double helix loop coil, a single helical loop coil with center return, a twisted twin lead coil, a coil having a convoluted path or alternating opposed solenoid coils in series. In one embodiment, the conductive coil can be integrated into device 150. During an MRI process, coils are helpful in providing phase information in different imaging and device orientations. Variable magnetic sensitivity patterns along a length of the coil cause phase discontinuities in an MRI signal that can be detected by the coil itself and/or an external coil such as RF coil 160.

At step 204, a magnetic resonance image is obtained of the device. Signals detected by external coil 160 and/or the coil 192 placed along device 150 can be used for obtaining the image. In some embodiments, phase information from these signals are used in generating an MR image.

RF energy from RF source 140 causes currents to flow in the coil along the length of the device. The current in the coil creates an associated magnetic field. Local magnetic field variations can result either from low frequency (DC) current, or from variation magnetic permeability with a resulting variation in material susceptibility, which are distinct phenomena but behave similarly. Magnetic susceptibility of portions of the conductive coil along the device cause a local phase shift (e.g., phase discontinuities, also known as shear) of magnetic resonance images taken along a length of the conductive coil due to these currents and the associated magnetic field. Generally, the phase shift is continuous away from the coil. At the coil, the magnetic field, and therefore the phase shift, can be a discontinuity in some cases.

In some instances, phase discontinuities can be difficult to detect due to orientation of the coil and/or orientation of the RF signal generated by the MRI system. Several techniques can be employed to identify one or more discrete locations on the coil in order to visualize the device along the coil in MR images. Phase discontinuities can also be difficult to determine due to phase ambiguities in which phases in comparative signals differ by a value of 2π. These phase ambiguities are said to be “wrapped”, and can be resolved using known “phase unwrapping” techniques.

Given the above situations, one technique that can be used according to step 204 is to obtain images along a thick imaging area (or slice) corresponding to several adjacent parallel planes. As a result of using the thick slice, phase discontinuities are more likely to be detected with respect to at least some of the planes within the imaging slice. Additionally, by periodically spacing coils of small width with respect to resolution of the image along the device, locations of the individual coils can easily be determined.

In another technique, varying phase shifting of images and temporal filtering are used to distinguish shear from phase wrap in complex phase images. For example, a separate encoding pulse can be used to cause a phase shift. In a further technique, an RF excitation can be transmitted through the device to create fringes, which are changes in magnitude of signal. This can result from cycling of the flip angle, as the excitation pulse decays with distance from the antenna. An optimum flip angle to create a maximum signal that locates positions in the coil can be determined by detecting phase using an external coil and/or the coil along the device. Alternatively, dephasing pulses can be transmitted through coils to drive a phase signal to zero, which causes residues in the phase image. As the phase signal changes from a positive value to a negative value, alternating residues can be detected and used to generate an image of the device.

In another embodiment, alternating coils can be used to generate alternating residues.

In another embodiment, a phase derivative variance and/or maximum phase gradient quality maps can be used to detect shear. Additionally, a maximum gradient from locally unwrapped phase data can be calculated to eliminate extraneous phase wrap artifact.

At step 206, an image representation is generated at the length of the device based upon signal phase variations in the obtained MR image. The phase variations indicate device position and orientation due to the discontinuities caused and/or detected by the coil along the device. In one embodiment, a mask generated from a magnitude interpretation of MRI information can be used with the phase variations to exclude unwanted phase noise. The resulting image representation can be used in a real-time setting to aid in visualizing and tracking interventional devices in an MRI process.

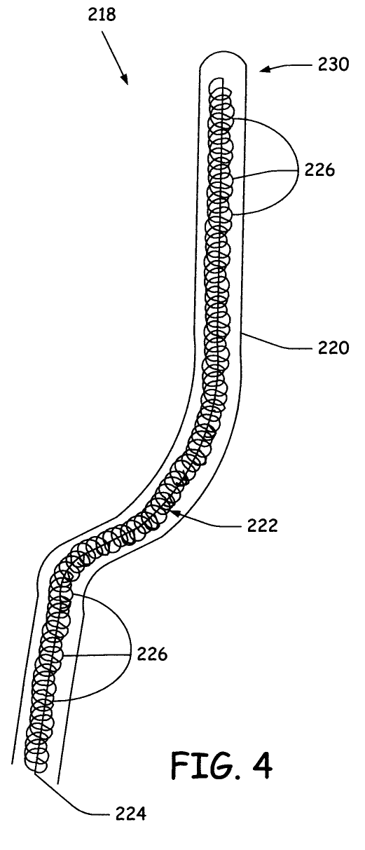

FIG. 4 is a cut-away view of a catheter device 218 in accordance with one example embodiment. Catheter device 218 includes an elongate coil assembly 222 carried within catheter sheath 220. Elongate coil assembly 222 is illustrated as a single wire which is of a conductive material. The elongate coil assembly includes a center conductor 224 which extends along the interior of the catheter sheath 220 to a distal end 230. At distal end 230, the direction of the center wire 224 is reversed and the wire is formed into a plurality of coils 226 in a direction toward a proximal end (not shown) of device 218. The diameter of the coils 226 and spacing can be selected as desired resolution and flexibility of the elongate coil assembly 222.

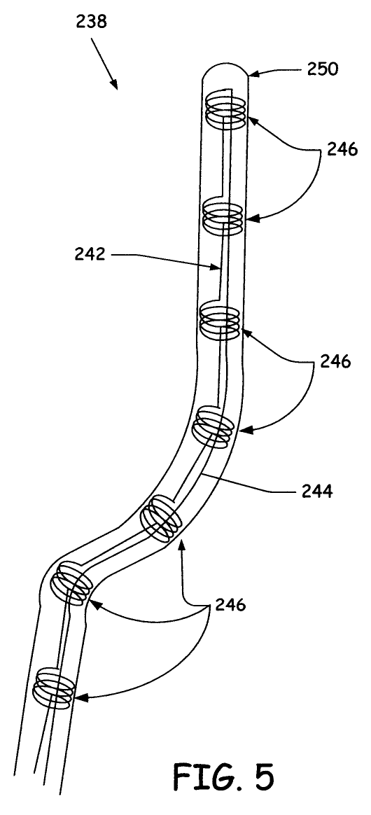

FIG. 5 is a cut away view of an embodiment illustrated in catheter 238 which is similar to the embodiment shown in FIG. 4. In FIG. 5, an elongate coil assembly 242 is formed of a center wire 244 which extends along an interior of catheter sheath 240 to a distal end 250. The wire forms a plurality of individual coils 246 along selected portions of the catheter 238 along a return path to a proximal end (not shown) of catheter 238. The spacing between the coils 246, the diameter of the windings of the coils, the spacing between individual windings within a particular coil 246 and the thickness of the wire used to make the coils can be selected as desired to achieve the desired properties for the elongate coil assembly 242, including the imaging resolution and physical properties of the coil.

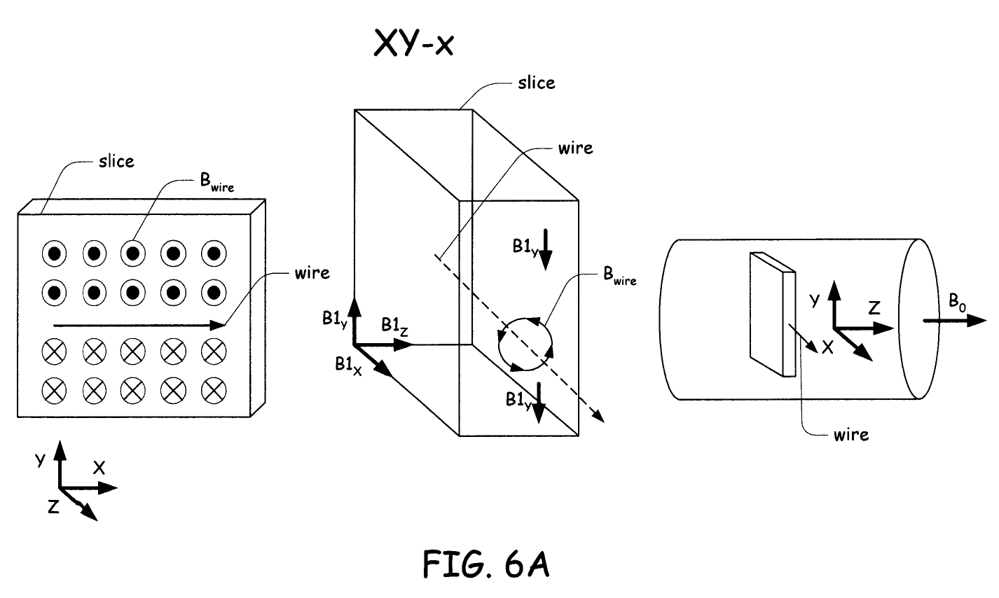

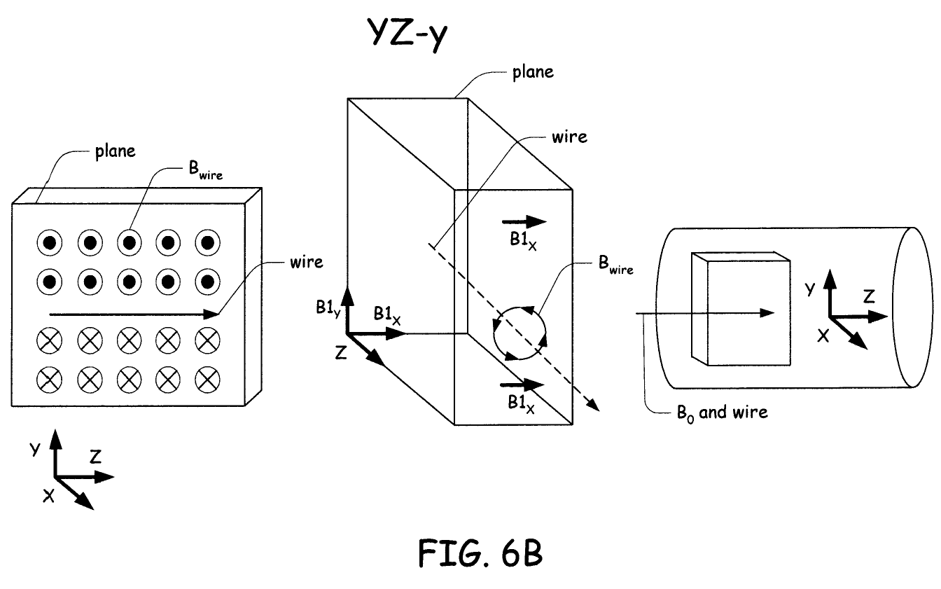

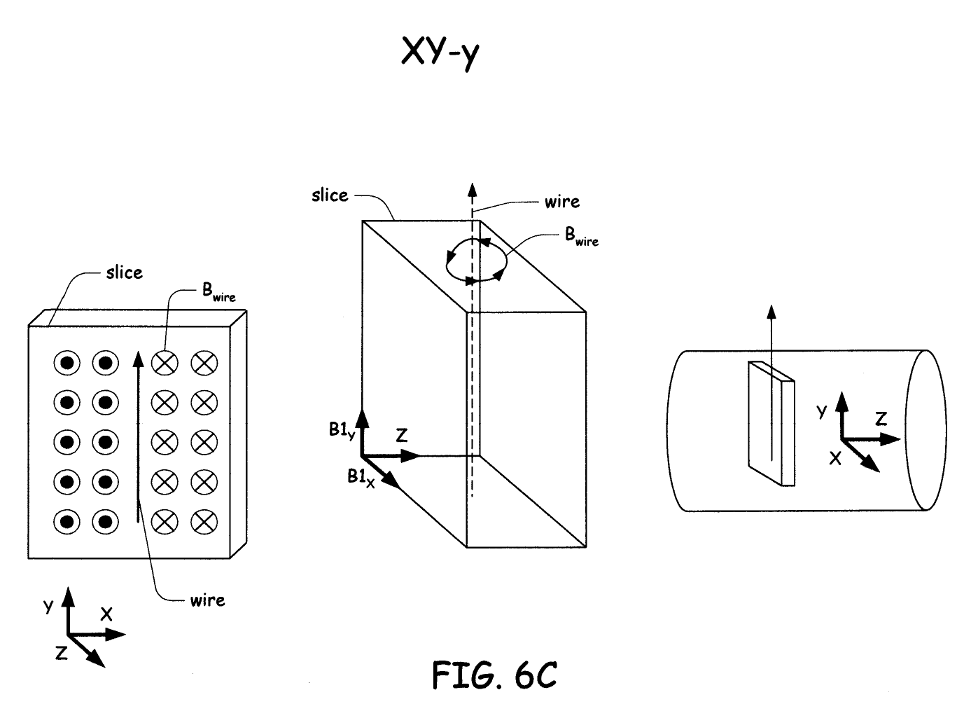

FIGS. 6A, 6B and 6C show three possible configurations and orientations of the wire of the coil assembly relative to the fields present in an imaging system. The wire which makes up the coil can lie in one of three directions defined in an X, Y and Z coordinate system, or any combination. In some embodiments, the phase change introduced by the wire of the coil is used to image the location of the coil, and therefore the device which contains the coil, in the imaging plane of the MRI system.

In the example of FIG. 6A, a coordinate system is shown in which the imaging “slice” is taken in the XY plane and the wire which forms the coil extends along in the x direction. In this coordinate system, the B₀ field (for example generated by magnetic field generator 120) extends in the Z direction and the B₁ field (for example generated by gradient generator 130) rotates about the Z axis with components in the X and Y direction. In this arrangement, the magnetic field from the wire (B_{wire}) that is generated by currents in the wire resulting from the magnetic resonance imaging system has components in the Y and Z direction. In this configuration, the phase signal arises from the Y component alone. Changes in B1_{Y} arise along the +/−Z offsets, or as the imaging plane moves along the Z axis, due to the diminishing strength of the magnetic field (B_{wire}) with distance from the wire. However, phase shifts through a thickness of a slice that contains the wire will tend to cancel each other (because phase shifts on the +Z side of the wire will be opposite to phase shifts on the −Z side). With such a configuration, errors in the phase image can be corrected, for example, with a 1π dephasing gradient. A twisted loop coil or Maxwell model pole configuration can also be employed. Multi-slice or other three dimensional imaging techniques can be used to locate and image the coil. In this last technique, multiple adjacent slices are compared so that opposite phase shifts on the +Z side and −Z side will apparent.

In the example of FIG. 6B, the imaging slice is taken in a YZ plane with the wire which forms the coil extending along the Z axis. In this configuration, B₀ extends in the Z direction with B₁ rotating around the Z axis and having components in the X and Y directions. The field components from the B_{wire} lie in the XY plane. In this configuration, the phase signal used for imaging of the coil arises from the X component alone. Changes in B1_{y} arise along the +/−X offsets, or as the imaging plane moves along the X axis. In addition, phase shifts through the thickness of a slice that contains the wire will tend to accumulate (because phase shifts on the +X side have the same polarity as phase shifts on the −X side), so that correction techniques are less likely to be required.

FIG. 6C shows a third example configuration in which the imaging slice is taken in an XY plane and the wire which forms the coil extending along the Y direction. Again, B0 extends in the Z direction with B1 rotating around the Z axis and having components in the X and Y directions. In this configuration, the B_{wire} components lie in the X and Z directions and the phase imaging signal arises only from the X components. Changes in B1ₓ arise along the +/−Z offsets, or as the imaging plane moves along the Z axis. As discussed above for the example in FIG. 6A, phase shifts through a thickness of a slice that contains the wire will tend to cancel each other. Imaging errors can be corrected using appropriate techniques including, for example, a 1π dephasing gradient. Example coil configurations including a twisted loop coil or a Maxwell monopole can be used to assist in visualization. Multi-slice or other three dimensional imaging techniques can be used for coil visualization.

Embodiments disclosed herein permit visualization of lengths or other configurations of elongate medical devices such as catheters and guide wires. Thus, the path of the elongate medical device through the subject can be visualized. This is in contrast to other techniques in which imaging is used for tracking through the calculation of one or more discreet locations on a device such as a catheter, often corresponding to small individual coils, with respect to an image. As used herein, visualization refers to the creation of a local image combined with another, larger image in such a way as to indicate the location of a device. In the case where a number of small coils are placed along a length of the device, the image of the device begins to blur. In one aspect, pattern matching techniques are used to identify characteristic catheter phase effects for use in visualization.

Through the visualization techniques disclosed, phase information which is detected by, or caused by, the coil assembly is used to define the location and orientation of an invasive medical device such as a guide wire, catheter, electrode, biopsy needle, etc. The phase discontinuity, i.e., shear, resulting from device detection or stimulation is used to track and/or visualize the medical device. Specific coil designs can be used to provide robust phase information in many imaging and device orientations. Such designs include a double helix loop coil, single helical loop coil with center return, twisted twin lead coil, alternating opposed solenoid cols connected in series, or other configurations.

As discussed earlier, catheters with alternating coil patterns along their length have been found to be less sensitive to device orientation. Varying phase shifting of images and temporal filtering can be used to distinguish shear from phase wrap in complex phase images. Catheters with periodic coil spacing can be detected by applying a spatiotemporal filter to the image. In another configuration, an RF excitation signal is transmitted through the coil assembly to create fringes by cycling the flip angle. These fringes are detected either through the coil assembly or through the external imaging coil. Most imaging schemes have an optimal flip angle that wields maximum signal. For spin echo sequences, that angle is 90°. At 180°, the signal is 0 and at 270° the signal is again a maximum.

In another configuration, the susceptibility of the coil assembly is used to cause a local phase shift. Additional phase and coding pulses can be transmitted through the coil assembly to cause a phase shift. Dephasing pulses can be transmitted through a finely textured coil to drive the signal to zero locally, thereby residues in the phase image. These residues can be used to provide an indication of catheter position. Alternating coils can be used to generate alternating residues which can also provide an indication of catheter position.

The imaging processing can be selected as desired. For example, a mask can be applied which is generated from signal magnitude to exclude unwanted phase noise in the final image. Phase derivative variants or maximum phase gradient quality maps can be used to detect shear, for example as described in “Two Dimensional Phase Unwrapping Theory, Algorithms and Software” by Dennis C. Ghiglia and Mark D. Pritt, published by John Wiley and Sons, 1998. A maximum gradient can be calculated from locally unwrapped phase data to eliminate extraneous phase wrap artifacts.

In general, the coil assembly and imaging plane orientation can be configured to provide well defined phase discontinuities that are more easily detected. However, since invivo catheter orientation must be assumed to be arbitrary, coils with variable sensitivity patterns along the length of the catheter are preferable. If the texture of the coils is sufficiently fine, positioning errors along the length of the catheter may be acceptable in exchange for increased precision of visualization information perpendicular to the catheter, as illustrated in FIGS. 6A-6C.

In general, implementations of the device, e.g., the medical device, can include an image acquisition technique, one or more sources of phase discontinuities, and one or more phase discontinuity detection techniques.

Image Acquisition

In some implementations, an MRI phase image is reconstructed using standard MRI techniques from the signals detected by the device antenna 192. The phase image from the device antenna can be superimposed on a background image generated, either previously or simultaneously, from coils external to the subject that provide a more uniform sensing of a larger region of interest. The background image can be magnitude image, although it can include phase information, e.g., for indicating velocity. The similar structures visible from the phase and background images can be used to aligned the images. The image from the device antenna will exhibit a discontinuity (caused by one of the effects discussed below), indicating the location of the device, thus enabling precise determination and representation of the device on the combined image.

In other alternative implementations, an MRI phase image is reconstructed using standard MRI techniques from the signals detected by the external RF receiver 160. The image from the external antenna will exhibit a discontinuity (caused by one of the effects discussed below), indicating the location of the device.

Source of Phase Discontinuities

In some implementations, the device 150 is formed of a material with a different magnetic susceptibility than the media in which it will be positioned, e.g., blood or tissue. Thus, the boundary between the device and the blood or tissue should be visible as a phase discontinuity on a phase image.

In some implementations, the device 150 includes adjacent regions formed of materials with different magnetic susceptibility. For example, the regions of the device can form a pattern, e.g., alternating bands of different magnetic susceptibility. The boundaries between these adjacent regions should be visible as a phase discontinuities on a phase image.

In some implementations, a DC or low frequency pulse is transmitted through the coil assembly on the device 150. This DC or low frequency pulse generates a magnetic field around the wire, thus cause local phase shifts in the materials adjacent the device. The direction and magnitude of the phase shift will depend on the orientation of the wire relative to the applied magnetic fields. However, in general, where the slice is parallel to the B0 field, the applied field and resulting phase shifts in the slice on opposite sides of the wire will be in opposite directions. In contrast, in general, where the slice is perpendicular to the B0 field, phase shifts will tend to cancel each other through the thickness of the slice. In this case, several compensating techniques can be used. First, a dephasing pulse can be applied to eliminate the cancellation. Second, multiple adjacent slices can be examined to detect the phase (phases will not cancel each other in slices immediately adjacent to the wire, thus sudden shift in phase in adjacent slices can generate a detectable discontinuity).

In some implementations, the device antenna is a coil assembly with varying coil configuration or density along the length of the device. For example, the coil assembly can include periodically spaced groups of coils connected by generally linear conductive segments. The variations in the coil assembly along the length of the device can generate variations in phase along the length of the device, such as phase discontinuities around each group of coils, which can be helpful in determining device position and orientation.

Detection of Phase Discontinuities

In some implementations, the image (i.e., the image analyzed to detect the phase discontinuity) is based on the phase data. In some implementations, the image is based on a first derivative of the phase data. In some implementations, the image is based on a second derivative of the phase data. In some implementations, phase discontinuities are detected from phase derivative variance. In some implementations, phase discontinuities are detected from maximum phase gradient. In some implementations, phase discontinuities are detected from quality maps can be used to detect shear. Additionally, phase data is locally unwrapped to eliminate extraneous phase wrap artifact.

The functional operations of the controller 170, including detecting the discontinuities in the signal phase variations, determining a position of the device based on detected discontinuities, generation of a reference image, e.g., by conventional MRI imaging techniques from the data from the external RF receiver 160, generation of an image representation of the device, and display of the image representation superimposed on the reference image, can be implemented in digital electronic circuitry, or in computer software, firmware, or hardware, or in combinations of them. In some embodiments, functions can be implemented as one or more computer program products, i.e., one or more computer programs tangibly embodied in a machine readable storage media, for execution by, or to control the operation of a processor, e.g., a programmable processor, a computer, or multiple programmable processors or computers.

Although FIG. 1 illustrates a human subject, the techniques described can be applicable to detection of devices used in non-human subjects, cadavers, or even in inanimate bodies.

A number of embodiments have been described. Nevertheless, it will be understood that various modifications may be made without departing from the spirit and scope of the invention. Accordingly, other embodiments are within the scope of the following claims.

What is claimed is:

1. A method of imaging a device in a magnetic resonance imaging system, comprising:
inserting a device having a conductive coil assembly thereon into a subject;
obtaining a magnetic resonance image of the subject, the magnetic resonance image including signal phase variations;
determining a position of the device based on discontinuities in the signal phase variations; and
displaying an image representation of the device superimposed on a reference image based upon the determined position.

2. The method of claim 1, wherein determining the position of the device includes detection of the discontinuities in the signal phase variations by a processor.

3. The method of claim 2, wherein determining the position of the device includes pattern recognition of the magnetic resonance image by a processor.

4. The method of claim 1, further comprising detecting signal phase variations using the conductive coil assembly.

5. The method of claim 1, further comprising detecting signal phase variations using an external coil of the magnetic resonance imaging system.

6. The method of claim 1, wherein the magnetic resonance image includes a magnitude signal and wherein generating comprises applying a mask generated from the magnitude signal to the image representation.

7. The method of claim 1, wherein the device is an elongate device and the elongate conductive coil assembly is an elongate conductive coil assembly.

8. The method of claim 7, wherein the elongate conductive coil assembly comprises a double helix coil.

9. The method of claim 7, wherein the elongate conductive coil assembly comprises a single helical loop coil with center return.

10. The method of claim 7, wherein the elongate conductive coil assembly comprises a twisted twin lead coil.

11. The method of claim 7, wherein the elongate conductive coil assembly comprises coil having a convoluted path.

12. The method of claim 7, wherein the elongate conductive coil assembly comprises coil having alternative opposed solenoid coils.

13. The method of claim 1, further comprising unwrapping signal phase variations in the magnetic resonance image.

14. The method of claim 1, further comprising distinguishing shear from phase wrap using a temporal filter.

15. The method of claim 1, further comprising distinguishing shear from phase wrap by varying phase shafting.

16. The method of claim 1, further comprising applying an RF excitation signal through the coil assembly.

17. The method of claim 1, further comprising obtaining the magnetic resonance image using the coil assembly.

18. The method of claim 1, further comprising using the susceptibility of the coil assembly to cause a local phase shift.

19. The method of claim 1, further comprising transmitting additional phase and coding pulses through the coil assembly.

20. The method of claim 1, further comprising transmitting dephasing pulses through the coil assembly.

21. The method of claim 1, further comprising identifying a location of the coil assembly using phase residues.

22. The method of claim 1, further comprising reducing phased noise using a mask generated from signal magnitude.

23. The method of claim 1, further comprising generating the reference image includes using phase derivative variants to detect shear.

24. The method of claim 1, wherein generating an image includes calculating maximum phase gradient from locally unwrapped phase data.

25. The method of claim 1, wherein the coil assembly has a variable sensitivity pattern along a length of the coil assembly.

26. A method of imaging an elongate device in a magnetic resonance imaging system, comprising:
placing an elongate conductive coil assembly along a length of the device;
obtaining a magnetic resonance image including signal phase variations; and
generating an image representation of the length of the device based upon the signal phase variations.

27. A magnetic resonance imaging system, comprising:
a radio frequency (RF) source;
an elongate conductive coil positioned to receive RF signals from the RF source:
an RF receiver positioned to receive RF signals from the RF source; and
a controller operably coupled to the conductive coil and the RF receiver and adapted to generate an image representation of a length of a coil based on signal phase variations received by at least one of the elongate coil and the RF receiver.

28. A magnetic resonance imaging system, comprising:
means for obtaining a magnetic resonance image containing signal phase variations; and
means for generating an image representation of a length of an elongate conductive coil based on the signal phase variations.

29. An invasive medical device, comprising:
an elongated body having a conductive coil assembly thereon; and
a plurality of regions formed of materials with different magnetic susceptibility.

30. The device of claim 29, wherein the plurality of regions form a pattern.

31. The device of claim 30, wherein the plurality of regions form alternating bands of different magnetic susceptibility.

32. The device of claim 29, wherein the device is a guide wire, catheter, electrode needle or biopsy needle.
